(19) United States
(12) Patent Application Publication
(10) Pub. No.: US 2024/0060830 A1
(43) Pub. Date: Feb. 22, 2024

(54) METHOD AND SYSTEM FOR DETECTING HEATING AT A CONNECTOR BETWEEN ELECTRICAL CABLES AND CONNECTORS SUITABLE FOR SUCH A METHOD

(71) Applicant: WIN MS, Orsay (FR)

(72) Inventors: Laurent Sommervogel, Jouy-en-Josas (FR); Arnaud Peltier, Gif-sur-Yvette (FR); Marc Olivas, Orsay (FR)

(21) Appl. No.: 18/260,737

(22) PCT Filed: Jan. 14, 2022
(86) PCT No.: PCT/FR2022/050081

§ 371 Date: Jul. 7, 2023

(30) Foreign Application Priority Data
Jan. 15, 2021 (FR) 2100368

(51) Int. Cl. G01K 11/125; G01K 3/00; G01K 7/22; G01K 1/024

(52) U.S. Cl. CPC G01K 11/125; G01K 3/005; G01K 7/22; G01K 1/024

(57) ABSTRACT

A method for detecting a hot spot at a connector (2) arranged on an electrical line, a heat-sensitive impedance module (4, 4a, 4b, 4c) being arranged at the connector (2), the electrical line and the heat-sensitive impedance module having an overall heat-sensitive impedance, the method comprising the following steps: determining a physical characteristic that is a function of said overall heat-sensitive impedance, and if said physical characteristic deviates from a predetermined reference value, emitting an alarm for detecting and locating a hot spot at said connector.

### CROSS-REFERENCE TO RELATED APPLICATIONS

This application is a national phase entry under 35 U.S.C. § 371 of International Patent Application PCT/FR2022/050081, filed Jan. 14, 2022, designating the United States of America and published as International Patent Publication WO 2022/153015 A1 on Jul. 21, 2022, which claims the benefit under Article 8 of the Patent Cooperation Treaty to French Patent Application Serial No. FR2100368, filed Jan. 15, 2021.

### TECHNICAL FIELD

The present disclosure relates to a method for detecting and locating heating at a connector forming a junction between current conductive cables. It further relates to a system for implementing such a method, as well as to connectors suitable for such a method.

### BACKGROUND

The present disclosure relates to a device for protecting electrical networks. It applies to the protection of all types of electrical networks irrespective of their nature, whether intended for electrical power or data transfer.

The protection of electrical installations, of any nature, is fundamental for the safety of people and property. Indeed, an electrical fault frequently causes a fire with disastrous consequences. An electrical fault may also cause an electrification of sensitive areas, or more dramatically, the electric shock of people.

Some installations may comprise bundles of cables used for supply, also called harnesses, of very great length. This is, for example, the case in aeronautics, and, in particular, in an Airbus A380 wherein the length of the harnesses can reach 500 km.

These harnesses can form complex topologies through junctions, whether they are connectors or splices. Statistically, it is known that junctions constitute the weak link of wired networks, since they account for a great majority of faults encountered. When significant electrical power is carried, a faulty junction becomes the site of local heating due to thermal losses dissipated by the Joule effect, or the spark from an electric arc.

A connector may be faulty for multiple reasons: incomplete engagement of the pins, twisted pins, broken pins, oxidation or degradation of materials, poor surface condition, improper tightening, presence of foreign bodies, moisture.

These anomalies can lead to three categories of faults:
clear faults, such as open circuits or short circuits,
soft faults, for example, by increasing contact resistance, such as an impedance fault,
intermittent faults, for example, loose connections and/or electric arcs.

Open circuits obviously cause failures, but rarely cause accidents as long as they do not create series fault arcs.

On the other hand, short circuits and impedance faults are problematic, since they can give rise to an abnormal increase in temperature, potentially leading to an alteration of the sheaths by melting the plastic. According to Joule's law, the energy released is proportional to the contact resistance, and to the square of the current circulating in the connector.

Electric arcs are even more serious, since the sparks they generate are sometimes sufficient to trigger an on-board fire, as has happened in the past. Electric arcs may either be parallel arcs (beginnings of a short circuit), or series arcs (beginnings of an open circuit).

In order to ensure the quality of contact of a junction when a system is delivered, it can be visually verified when there is visual access, or by a continuity test when there is mechanical access at both ends. During the life of the system, there may be regular checks during maintenance phases that can be carried out either by visual inspection or by continuity test when possible.

### BRIEF SUMMARY

The present disclosure aims to detect, or even locate, soft faults and intermittent electric arc faults.

Several technologies can be considered for checking the temperature of a connection:
optical infrared technology, which has the disadvantage of its bulk and requires one sensor per connection,
optical fiber technology, which has the disadvantage of passing an optical fiber over each of the links and integrating a measurement system,
optical technology by probe/thermocouple, which has the disadvantage of its bulk and requires one sensor per connection,
acoustic technology, which has the disadvantage of applying only to arcs,
radio technology, which has the disadvantage of applying only to arcs.

An objective of the present disclosure is to overcome these faults by proposing a method and device for detecting, or even locating, hot spots at a connector, of reduced bulk compared to the prior art, lightweight, without adding power supply and communication bus necessary for an additional sensor.

One aim of the disclosure is notably to remedy all or part of the aforementioned drawbacks.

According to a first aspect of the present disclosure, a method is proposed for detecting a hot spot at a connector capable of forming a junction between current conductive cables of a first electrical line and a second electrical line, the connector being arranged on the first electrical line, a heat-sensitive impedance module being arranged integrated within the connector, the electrical line and the heat-sensitive impedance module having an overall heat-sensitive impedance, the method comprising the following steps:
determining a physical characteristic that is a function of the overall heat-sensitive impedance by measuring a physical quantity, and
if the determined characteristic deviates from a predetermined reference value, emitting an alarm for detecting and locating a hot spot at the connector.

A method is thus proposed for detecting a hot spot at a conductor, of reduced bulk compared to the prior art, lightweight, without adding the power supply and communication bus that would be required for an additional sensor.

Preferably, the method further comprises an estimation of the temperature at the temperature-sensitive impedance module determined from the determined characteristic.

The determined characteristic may, for example, be obtained by reflectometry. The reflectometry may, for example, use a signal whose autocorrelation function is a Dirac pulse. The reflectometry may, for example, be of the multicarrier type in the MCTDR (Multi-Carrier Time Domain Reflectometry) time domain, or of the multitone orthogonal type in the OMTDR (Orthogonal Multi-tone Time Domain Reflectometry) time domain. An SSTDR (Spread Spectrum Time Domain Reflectometry) type reflectometry can be implemented. The reflectometry also makes it possible to locate the detected hot spot.

According to a second aspect of the present disclosure, a system is proposed for detecting and locating a hot spot within an electrical connection capable of forming a junction between current conductive cables of a first electrical line and a second electrical line, the connector being arranged on the first electrical line, implementing the method according to the first aspect of the present disclosure, or one or more of improvements thereof, this system comprising:
at the connection, a heat-sensitive impedance module integrated into a connector equipping the electrical line, and
at a distance from the connection, a detection and location device comprising a reflectometry module configured to implement a determination of a physical characteristic that is a function of the overall heat-sensitive impedance by measuring a reflection coefficient, and a module for processing the data coming from the reflectometry equipment, in order to generate an alarm for detecting and locating a hot spot at the connector in the event a determined physical characteristic deviates from a predetermined reference value.

The detection and location device may at least comprise:
a unit for coupling to an electrical grid;
an injection unit configured to generate a high-frequency electrical signal, the signal being injected into the network via the coupling unit;
an acquisition unit capable of receiving a return signal from an injected signal, via the coupling unit, the acquisition unit digitizing the received signals;
a data control and processing unit connected at least to the acquisition unit, the control and processing unit analyzing the digitized data provided by the acquisition unit;
a communication unit connected to the control and processing unit capable of emitting the alarm for detecting and locating a hot spot.

According to a third aspect of the present disclosure, a connector is proposed that is able to form a junction between current conductive cables of a first electrical line and a second electrical line, the connector being arranged on the first electrical line and integrating a heat-sensitive impedance module, the connector being adapted to implement the method according to the first aspect of the present disclosure, or one or more of improvements thereof.

In a first embodiment, the connector incorporates a heat-sensitive conductivity module of a heat-sensitive resistivity material provided to at least partially surround the electrical line when the latter is electrically connected to the connector.

In a second embodiment, optionally compatible with the first embodiment, the connector incorporates a heat-sensitive resistance module provided with a dipole comprising a thermistor, the dipole being intended to be mounted on the electrical line.

In a third embodiment, optionally compatible with the first embodiment and/or the second embodiment, the connector incorporates a heat-sensitive capacitance module having a heat-sensitive rigidity.

According to a fourth aspect of the present disclosure, a method is proposed for instrumenting an electrical grid, wherein the method comprises a step of connecting into the electrical network a connector forming a junction between current conductive cables of a first electrical line and a second electrical line of the electrical network, the connector being in accordance with the third aspect of the present disclosure, or one or more of the improvements thereof.

### BRIEF DESCRIPTION OF THE DRAWINGS

Other advantages and special features of the disclosure will become apparent on reading the detailed description of implementations and embodiments, which are in no way exhaustive, with reference to the appended drawings, in which:

FIG. 1 schematically shows a block diagram of an embodiment of a device according to the present disclosure;

FIG. 2 schematically shows an embodiment of a heat-sensitive conductivity module of the device shown in FIG. 1;

FIG. 3 schematically shows another embodiment of a heat-sensitive resistance module of the device shown in FIG. 1; and

FIG. 4 schematically shows another embodiment of a heat-sensitive capacitance module of the device shown in FIG. 1.

### DETAILED DESCRIPTION

Since the embodiments described below are in no way limiting, it will, in particular, be possible to consider variants of the present disclosure comprising only a selection of the features described, subsequently isolated from the other features described, if this selection of characteristics is sufficient to confer a technical advantage or to differentiate the present disclosure from the prior art. This selection comprises at least one feature, preferably functional, without structural details, or with only a portion of the structural details if this part only is sufficient to confer a technical advantage or to differentiate the present disclosure from the prior art.

In the figures, an element appearing in several figures retains the same reference.

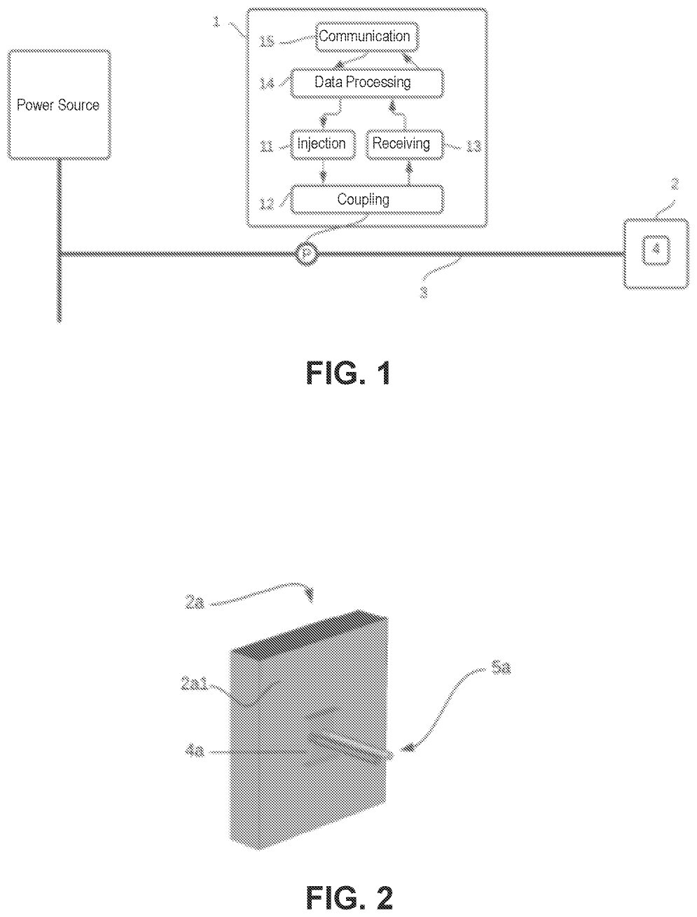

A fault detection module 1 is now described with reference to FIG. 1, at the same time as the method implemented in this system.

The fault detection module 1 is provided to detect and locate faults at one or several connectors 2 arranged at the junction of an electrical line 3 and another electrical line (not shown).

The device for detecting and locating a hot spot according to the present disclosure comprises a heat-sensitive conductivity module 4, acting as a target, arranged at the connector 2, and the data processing module 1 remote from the connector 2.

The fault detection module 1 is configured to implement an impedance measurement of the electrical line, and if the measurement deviates from a reference value (the impedance mismatch becomes detectable on the line), to generate an alarm for detecting and locating a hot spot at the connector.

According to one possibility, the fault detection module 1 operates according to the reflectometry principle. This principle is close to that of radar. An electrical signal, generally at high frequency or broadband, is injected into one or more locations of a network of cables in which a fault is likely to be detected. The signal propagates over the network and returns part of its energy when it encounters an electrical discontinuity, that is to say, a modification of impedance. In a simple case, the signal propagates along a two-wire electrical supply line, two conductors at least being necessary for its propagation. The present disclosure applies for all other types of cables comprising one or more wires, in particular, for three-wire cables, coaxial cables or cables referenced to a ground plane. An electrical discontinuity may result from a fault. The analysis of the signals returned to the injection point makes it possible to deduce therefrom information about the presence, nature and location of these discontinuities, therefore, of possible faults.

The fault detection module 1 used in a device according to the present disclosure comprises blocks making it possible to implement this principle of detection and location by reflectometry. It, therefore, comprises an injection unit 11 and a coupling unit 12. The injection unit, in particular, comprises a generator delivering a voltage that forms the injection signal, also referred to as a probe signal. The generator is, for example, programmable.

The injection unit 11 generates an injection signal that is injected at a point of the electrical line 3 of the network via the coupling unit 12. To this end, the coupling unit 12 is coupled to a point P of the network, this point being the input point of the injection signal. The electrical line on which the system is coupled being two-wire, a connection is made at a first point of a conductor and the other connection is made at a second point on the other conductor, opposite the first point. In a multi-conductor application with ground plane, coupling by connection at one point of a conductor and the other connection on the ground plane can be achieved.

The coupling unit 12, in particular, has the function of: injecting the probe signal between two conductors of the line being monitored; and receiving the probe signal between two conductors of the line being monitored.

The coupling unit 12 may also have the function of: protecting the detection system from the native signal of the line; protecting the system against attacks related to the environment (lightning, etc.) directing the probe signal to the line being monitored, the latter being part of a network formed by several lines, a directional coupling then being involved.

The fault detection module 1 also comprises an acquisition unit 13 able to receive the signals returned by the discontinuities encountered by the emitted injected signal. These returned signals are transmitted to the acquisition unit via the coupling unit 12. The acquisition unit 13 comprises, for example, one or more matched filters, one or more low-noise amplifiers and one or more analog-digital converters.

The fault detection module 1 also comprises a data control and processing unit 14. This data control and processing unit 14 is connected to the injection unit 11 and to the acquisition unit 13. In particular, it makes it possible to control the programmable generator of the injection block. It receives the digitized reception signals provided by the acquisition unit 13. In particular, it performs the processing of these digital data to confirm or not the presence of a fault as well as its location.

The fault detection module 1 further comprises a communication unit 15 enabling it to communicate with other systems, a supervision system, for example. The communication unit 15, in particular, allows the data control and processing unit 14 to control a supervision system in the event of a proven fault. The communication unit 15 may be of the wireless type. A secondary cable can also be used as a communication line. The communication unit 15 can also receive information from other members and thus allow the data control and processing unit 14 to take external elements into account in the decision making. This can advantageously be used when a component, a switch, for example, on a protected line changes state. The processing block then knows that it is a normal event in the operation of the system and not a fault.

The fault detection module 1 injects into the network a signal whose frequency spectrum disrupts neither the useful signals present on the line nor the environment of the cables of the network while complying, in particular, with the frequency templates relating to the EMC electromagnetic requirements. The repetition period of the injected signal must be short enough to allow the fault detection module to detect a first fault potentially able to destroy an installation, thus the repetition period may be less than 500 μs, or even shorter. To this end, the injected signal can advantageously be generated according to multicarrier reflectometry methods, for example, of the MCTDR (Multi-Carrier Time Domain Reflectometry) type, or other methods having the same frequency characteristics. For bandwidth constraints of the electrical lines 3 of the network, the signals use, for example, frequencies between 100 kHz and 200 MHz with an amplitude less than one volt and a periodicity of the order of a hundred microseconds.

In a prior phase, the parameterization of the fault detection module 1 is carried out by determining a detection threshold corresponding to a variation, taken as absolute value, predetermined minimum value of the reflection coefficient. The reflection coefficient is the measurement derived from the reflectometry experiment: this is the ratio between the reflected voltage and the incident voltage along the line. It is, therefore, a unit-free quantity comprised between −1 (short-circuit) and +1 (open circuit).

Any change in resistance, conductivity or capacitance ultimately results in a variation of the reflection coefficient. Also, in the following examples, the physical characteristic depending on the impedance of the overall heat-sensitive impedance is the reflection coefficient obtained by reflectometry.

Advantageously, reflectometry can give access to the reflection coefficient as a function of the distance to the injection point. The impedance may optionally be deduced by calculation, as well as a function of the distance to the injection point.

The threshold to be set is, therefore, only on this reflection coefficient, and is, therefore, also without a unit. It is typically possible to set it to +/−10% (therefore, a threshold at 0.1 in absolute value). A fault is detected when a reflected signal, resulting from encountering a discontinuity in the network, is greater in absolute value than this threshold. This threshold may be variable.

Several embodiments of heat-sensitive conductivity modules 4 are now described.

Heat-Sensitive Conductivity Material Module

With reference to FIG. 2, it is proposed to integrate a heat-sensitive conductivity module 4a into a connector 2a having a connector base 2a1. The principle is to partially embed each line to be monitored (not shown), or pins 5a that are suitable for cooperating with the electrical line in a heat-sensitive conductivity material that forms the heat-sensitive conductivity module 4a.

It is typically possible to use a material of the eutectic salt type. At ambient temperature, these salts are solid and insulating. At high temperature, these salts are liquid and conductive.

The connector is not limited to a pair of pins, it would be conceivable that there are others covering the surface of the connector 2a in its entirety.

This material is determined so that its insulation properties vary with temperature, in particular, so that its resistivity p is a function of the temperature. The conductivity between the pins 5a is, therefore, written as a temperature-dependent function:

$$\\ G ( T ) = \frac{S}{l ρ ( T )} = {G}_{0} \frac{ρ ( {T}_{0} )}{ρ ( T )}$$

where S denotes the effective cross section between the pins and/their separation.

At normal ambient temperature, T=T₀ and, therefore, g=G₀. By choosing G₀ sufficiently small (in any case G₀«1/Z_{c}, Z_{c} being the characteristic of the line), the absence of abnormal temperature rise leads the device to behave in a transparent manner (as though it were not there).

As soon as the temperature increases, the conductivity increases and the impedance mismatch becomes detectable, but not sufficiently to modify the behavior of the monitored system (for example, with respect to the conductive power).

This implementation of the present disclosure clearly leads to the desired objective: in the event of a rise in temperature, a strong marker (the impedance mismatch) quickly makes it possible to detect and locate the fault, but the impact on the basic functionality is not aggravated. The mismatch further makes it possible to estimate the conductivity and, therefore, to deduce therefrom an estimate of the temperature.

Electronic Type Module

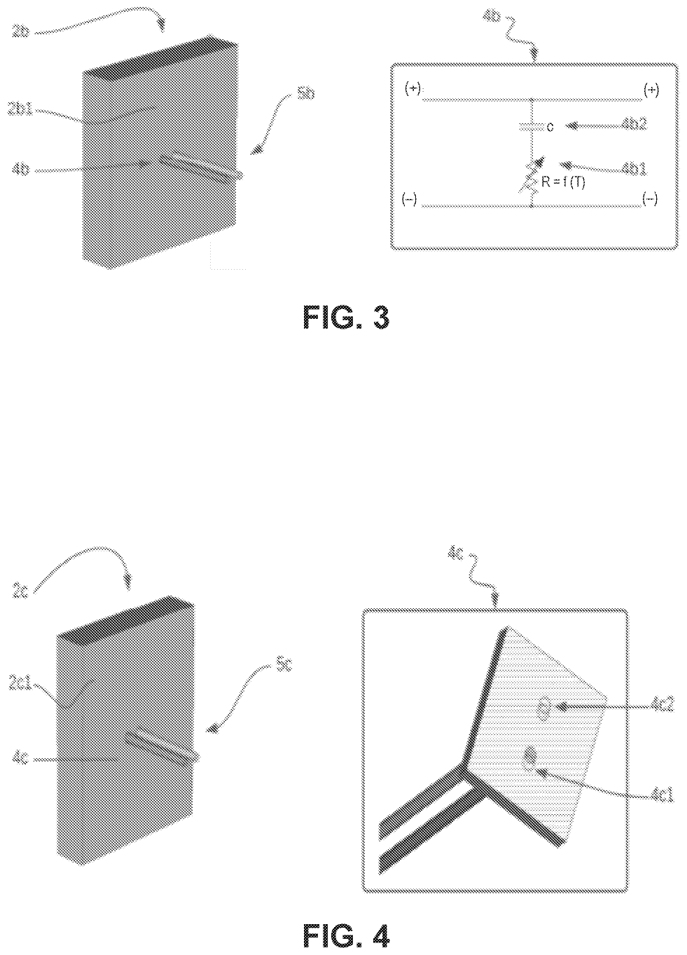

With reference to the left part of FIG. 3, it is proposed to integrate a heat-sensitive resistance module 4b into a connector 2b having a connector base 2b1.

With reference to the right part of FIG. 3, the heat-sensitive resistance module 4b comprises a thermistor 4b1 in series with a capacitor 4b2, as well as two electrical poles to be connected to a line of the electrical grid at each junction. Typically, the thermistor may have a value of 10 kOhms at room temperature and 1 Ohm at hot temperature. Typically, the capacitor has a value of 100 nF.

The thermistor (for example, with a negative temperature coefficient) is an electronic component whose resistance depends on temperature according to the approximate law:

$$\\ R ( T ) = {R}_{0} {e}^{β} ( \frac{1}{T} - \frac{1}{T 0} )$$

where β is a specific coefficient of the thermistor.

At normal ambient temperature, T=T₀ and, therefore, R=R₀. By choosing R₀ sufficiently large (in any case R₀ »Z_{c}, Z_{c} being the characteristic of the line), the absence of abnormal temperature rise leads the device to behave in a transparent manner (as though it were not there).

As soon as the temperature increases, the resistance decreases and the capacitance C is placed in parallel on line. The value of C is chosen so that the capacitor is seen as a short-circuit by high-frequency signals, which the person skilled in the art knows how to do, but it is transparent for low frequencies.

Negative temperature coefficient thermistors can be used in a wide range of temperatures, from −200 to +1000° C., and they are available in different versions: glass beads, discs, bars, pellets, washers or chips. The nominal resistances range from a few ohms to a hundred kilo ohms.

This implementation of the present disclosure leads clearly to the desired objectives: in the event of a rise in temperature, a strong marker (the drop in impedance) quickly makes it possible to detect and locate the fault, but the impact on the basic function is not aggravated. The estimation of the resistance further makes it possible to deduce an estimation of the temperature.

Mechanical Type Module

With reference to the left part of FIG. 4, it is proposed to integrate a heat-sensitive capacitance module 4c into a connector 2c having a connector base 2c1 and pins 5c.

In this implementation, the idea is to use bottoms of connectors 4c1 that are not completely rigid, sufficiently deformable so that expansion under the effect of increasing temperature causes localized movement of each line to be monitored, which is illustrated on the right-hand part of FIG. 4 by two circles 4c1 and 4c2 indicating the movement. The person skilled in the art will know how to choose such materials.

The connection is of course not limited to a pair of conductors; it would be conceivable that there are others in the same connector.

The connector is shown in a single block, but in reality it may be made of different materials.

The more the temperature increases, the greater the movement and the more the capacitance will vary. It may be provided to favor a direction of movement tending to increase the spacing, which reduces the capacitance.

The variation in spacing e=f(T) leads to a dependency of the capacitance as a temperature-dependent function:

$$\\ C ( T ) = {ϵ}_{0} {ϵ}_{R} \frac{S}{e ( T )} = {C}_{0} \frac{e ( {T}_{0} )}{e ( T )}$$

where ∈₀ denotes the permittivity of the vacuum, ∈_{R} the dielectric permittivity of the insulator and S the cross section of the connection area.

At normal ambient temperature, T=T₀ and, therefore, C=C₀. By choosing C₀ close to the linear capacitance of the line (in any case, so as to minimize the mismatch of impedance in the connector), the absence of abnormal temperature rise leads the device to behave in a transparent manner (as though it were not there).

As soon as the temperature increases, the capacitance varies (and decreases if the lines move apart) and the mismatch of impedance becomes detectable, but not sufficiently to modify the behavior of the monitored system (for example, with respect to the conductive power).

As a first approximation, the capacitance varies in the same proportions as the mechanical movement. For a typical movement of 10% relative to the nominal spacing, the capacitance has a drop of 10%. The drop in capacitance of 10% again generates a variation of any unit (in percentages) on the reflection coefficient.

In this embodiment, the detection threshold to be set may typically be set to +/−5% (therefore, a threshold at 0.05 in absolute value). A fault is detected when a reflected signal, resulting from encountering a discontinuity in the network, is greater in absolute value than this threshold. This threshold may be variable.

This implementation of the present disclosure clearly leads to the desired objectives: in the event of a rise in temperature, a strong marker (the impedance mismatch) quickly makes it possible to detect and locate the fault, but the impact on the basic functionality is not aggravated. The mismatch further makes it possible to estimate the capacitance and, therefore, to deduce therefrom an estimate of the temperature.

Several embodiments of a device according to the disclosure are possible.

It is also possible to separate the coupling unit 12 from the other components of the fault detection module 1. This embodiment is particularly suitable for the protection of high-voltage lines. The coupling unit is thus placed as close as possible to the line while being separated from the rest of the detection system. The connection between the coupling unit and the detection system is done via a homogeneous and controlled impedance connection, for example, a pair of twisted wires or a 50 ohms coaxial cable. In another embodiment, the coupling may be wireless.

Advantageously, the coupling may be directive as indicated above. In this case, the device detects faults in one direction only, this direction being predetermined. This coupling mode is particularly suitable when several lines to be protected are connected to a bus bar, the power supply current circulating from the bus bar to loads via the lines. Since the bus bar has a low impedance relative to the lines, the probe signal moves naturally toward the bus bar. The directional coupling makes it possible to orient the probe signal downstream, that is to say, toward the loads. The directional coupling can be carried out in several ways. For example, an upstream self-inductance can be inserted while adjusting the frequency of the probe signal in order to increase the upstream impedance. Advantageously, a device according to the present disclosure makes it possible to detect and respond quickly to several types of faults, or even to anticipate them. The measurements from the reflectometer, in particular, the changes in impedance or of variation in propagation speed, can be used to establish a connector diagnosis. Thus, the control and processing unit can be programmed to establish such a diagnosis, based, for example, on parameters of connectors, thresholds, events or predefined signatures characteristic of a connector state.

The present disclosure can also be applied to protect connectors from telecommunications networks or power networks where carrier currents circulate. Advantageously, the reflectometry method does not disturb the data transfers within the network provided that the appropriate frequency bands of the probe signal emitted in the network or other methods are chosen in order to differentiate the signals.

Also advantageously, the device according to the disclosure can operate while the network is not under power, unlike conventional solutions for current and voltage analysis that require that the network be electrically powered. This makes it possible, in particular, to monitor a network before it is powered up.

Advantageously, the detection system by reflectometry can issue information about the location of an electrical fault. This information can then be exploited by the maintenance services.

Advantageously, a device according to the present disclosure can be parameterized to protect one or more line areas and, therefore, one or more connectors on a line. Detection parameters can also be set as a function of the type of load or of the line area, in particular, the sensitivity of the detection. As an example, to protect a connector located at a given distance from the device, for example, 10 meters, a detection is carried out on the area between 9.5 meters and 10.5 meters. In this case, the processing means only process the modifications of impedances detected at connectors in the area to be protected.

In an alternative embodiment of a device according to the present disclosure, the communication unit 15, the data control and processing unit 14, the injection unit 11 and the acquisition unit 13 can be shared, that is shared among several lines (and, therefore, connectors) by inserting one or more multiplexers between the injection units 11 and acquisition units 13 and coupling units 12 specific to each line. In other words, coupling units 12 are assigned to each of the lines and connectors, the connections between the coupling units and the injection and acquisition units being ensured by the one or more multiplexers.

Of course, the present disclosure is not limited to the examples that have just been described and numerous modifications can be made to these examples without departing from the scope of the present disclosure. In addition, the different features, forms, variants and embodiments of the present disclosure may be associated with one another in various combinations insofar as they are not incompatible or exclusive of one another.

Other physical characteristics of the impedance of the overall heat-sensitive impedance can be used.

This may, for example, be the measurement of a conductivity, for example, in the context of implementing a fault detection module, for example, according to that described with reference to FIG. 2.

This may, for example, be the measurement of a resistance, for example, in the context of implementing a fault detection module, for example, according to that described with reference to FIG. 3.

This may, for example, be the measurement of a capacitance, for example, in the context of implementing a fault detection module, for example, according to that described with reference to FIG. 4.

To carry out such measurements, the person skilled in the art has several well-known devices, not described further, such as RLC-meters.

It is thus possible to instrument an electrical network comprising connectors without adding an additional electrical circuit.

In the context of a pre-existing electrical network, only the connectors of the electrical network, or part thereof, are to be replaced by connectors according to the present disclosure, that is integrating the heat-sensitive impedance module.

In the context of the installation of an electrical network, it is possible to instrument the electrical network by arranging such connectors at the time of installation.

Furthermore, the analysis of the spatio-temporal variation of the physical characteristic detects hot spots not only at the connectors, but also monitors the electrical network by detecting short-circuit, open-circuit, or soft fault on the electrical cable, such as a clamped, damaged cable or a shunt.

In particular, the present disclosure can be extended to any field of application wherein it is sought to detect and locate hot spots. It is, for example, possible to implement the present disclosure in industrial environments such as monitoring pressurized tanks, and steam ducts in nuclear power plants.

1. A method for detecting a hot spot at a connector (2) able to form a junction between current conductive cables of a first electrical line and a second electrical line, the connector being arranged on the first electrical line, a heat-sensitive impedance module (4, 4a, 4b, 4c) integrated within the connector (2), the electrical line and the heat-sensitive impedance module having an overall heat-sensitive impedance, the method comprising the following steps:
a. determining a physical characteristic that is a function of said overall heat-sensitive impedance by measuring a physical quantity, and
b. if said determined characteristic deviates from a predetermined reference value, emitting an alarm for detecting and locating a hot spot at said connector.

2. The method according to the preceding claim, further comprising an estimation of the temperature at the heat-sensitive impedance module (4) determined from said determined characteristic.

3. The method according to claim 1 or 2, wherein the determined characteristic is a reflection coefficient obtained by reflectometry.

4. The method according to the preceding claim, wherein the reflectometry uses a signal whose autocorrelation function is a Dirac pulse.

5. A system for detecting and locating a hot spot within an electrical connection capable of forming a junction between current conductive cables of a first electrical line and a second electrical line, the connection being arranged on the first electrical line, implementing the method according to any one of the preceding claims, this system comprising:
at said connection, a heat-sensitive impedance module (4, 4a, 4b, 4c) integrated into a connector equipping said electrical line, the electrical line and the heat-sensitive impedance module having an overall heat-sensitive impedance, and
at a distance from said connection, a detection and location device comprising a reflectometry module configured to implement a determination of a physical characteristic that is a function of said overall heat-sensitive impedance by measuring a reflection coefficient, a module for processing the data coming from said reflectometry equipment, in order to generate an alarm for detecting and locating a hot spot at said connector in the event of a determined physical characteristic deviating from a predetermined reference value.

6. The system according to the preceding claim, characterized in that the detection and location device comprises at least:
a. a unit (12) for coupling to an electrical grid;
b. an injection unit (11) configured to generate a high-frequency electrical signal, said signal being injected into said network via the coupling means;
c. an acquisition unit (13) able to receive a return signal from an injected signal, via the coupling means, said acquisition unit digitizing the received signals;
d. a data control and processing unit (14) connected at least to the acquisition unit (13), said control and processing unit analyzing the digitized data provided by the acquisition unit;
e. a communication unit (15) connected to the control and processing unit capable of emitting the alarm for detecting and locating a hot spot.

7. A connector suitable for forming a junction between current conductive cables of a first electrical line and a second electrical line, said connector being arranged on the first electrical line and integrating a heat-sensitive impedance module (4, 4a, 4b, 4c), adapted to the method according to any one of claims 1 to 4.

8. The connector according to the preceding claim, integrating a heat-sensitive conductivity module (4a) of a heat-sensitive resistivity material provided to at least partially surround the electrical line when the latter is electrically connected to the connector (2a).

9. The connector according to one of the two preceding claims, integrating a heat-sensitive resistance module (4b) comprising a dipole comprising a thermistor, said dipole being intended to be mounted on the electrical line.

10. The connector according to any one of the three preceding claims, integrating a heat-sensitive capacitance module (4c) having a heat-sensitive rigidity.

11. A method for instrumenting an electrical network, characterized in that it comprises a step of connecting into the electrical network a connector forming a junction between current conductive cables of a first electrical line and a second electrical line of said electrical network, the connector being in accordance with any one of the last four claims.
